(19) United States
(12) Patent Application Publication
(10) Pub. No.: US 2026/0173540 A1
(43) Pub. Date: Jun. 18, 2026

(54) SILICON CONTROLLED RECTIFIER (SCR), INTEGRATED CIRCUIT (IC) CHIP INCLUDING SCR, AND METHODS OF FORMING SCR

(71) Applicant: GLOBALFOUNDRIES U.S. Inc., Malta, NY (US)

(72) Inventors: Anupam DUTTA, Kolkata (IN); Vvss Satyasuresh CHOPPALLI, Bengaluru (IN); Rajendran KRISHNASAMY, Essex Junction, VT (US); Judson Robert HOLT, Ballston Lake, NY (US)

(21) Appl. No.: 18/984,658

(22) Filed: Dec. 17, 2024

(51) Int. Cl. H10D 89/60; H10D 18/00; H10D 18/01

(52) U.S. Cl. CPC H10D 89/713; H10D 18/031; H10D 18/211

(57) ABSTRACT

A silicon controlled rectifier (SCR) includes a first well, a second well, a first well contact formed in the first well, a second well contact formed in the second well, a first junction contact raised compared to the first well contact, and a second junction contact raised compared to the second well contact.

### BACKGROUND

The present disclosure relates to semiconductor structure, more particularly, to silicon controlled rectifier (SCR) devices and methods of manufacture.

A silicon controlled rectifier (SCR) is a semiconductor device used for controlling a current. For example, an SCR is used to protect integrated circuits (ICs) from an electro-static discharge (ESD) event.

### SUMMARY

Embodiments of the present application relate to an SCR, an IC chip including the SCR, and a method of forming the SCR. For example, the SCR includes junction contacts raised compared to well contacts.

In an embodiment, a silicon controlled rectifier (SCR) includes a first well, a second well, a first well contact disposed in the first well, a second well contact disposed in the second well, a first junction contact raised compared to the first well contact, and a second junction contact raised compared to the second well contact.

In an embodiment, an integrated circuit (IC) includes a protected device and a silicon controlled rectifier (SCR) coupled between an I/O pad and the protective device. Such an SCR includes a first well, a second well, a first well contact disposed in the first well, a second well contact disposed in the second well, a first junction contact raised compared to the first well contact, and a second junction contact raised compared to the second well contact.

In an embodiment, a method of forming a silicon controlled rectifier (SCR) includes forming a first well contact in a first well, forming a second well contact in a second well, forming a first junction contact raised compared to the first well contact, and forming a second junction contact raised compared to the second well contact.

### BRIEF DESCRIPTION OF THE DRAWINGS

FIG. 1 illustrates a schematic view of an integrated circuit (IC) according to an embodiment.

FIGS. 2A and 2B illustrate an SCR according to an embodiment.

FIGS. 3A, 3B, 3C, and 3D illustrate a method of fabricating an SCR according to an embodiment.

FIG. 4 illustrates I-V characteristics of SCRs according to embodiments.

FIGS. 5A and 5B illustrate an SCR according to an embodiment.

### DETAILED DESCRIPTION

A detailed description of embodiments is provided below along with accompanying figures. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

As used in the present disclosure, including in the claims, a list of items prefaced by a phrase such as “at least one of,” “one or more of,” or “one or both of” indicates an inclusive list. For example, one or more of A, B, and C indicates A or B or C or AB or AC or BC or ABC (i.e., A and B and C).

In the present disclosure, an element may be designated monocrystalline when crystal lattice structure thereof has a long-range order of arrangement and lacks grain boundaries associated with a polycrystalline semiconductor material. Such an element may be considered to be monocrystalline even if crystallographic defects, such as dislocations, are incorporated as imperfections.

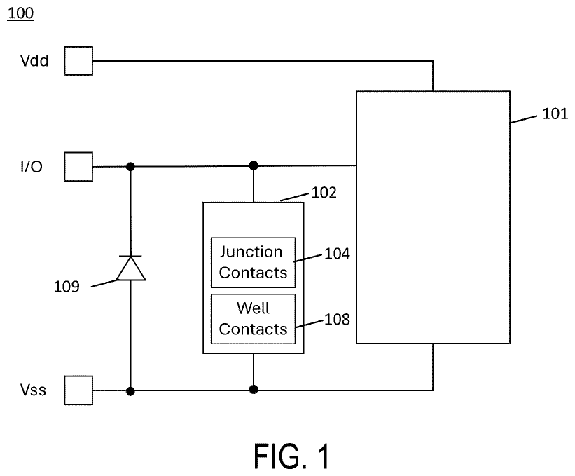

FIG. 1 illustrates a schematic view of an integrated circuit (IC) 100 according to an embodiment. The IC 100 in FIG. 1 includes a protected device 101, an input/output pad I/O, a supply voltage Vdd, and ground Vss, a diode 109, and an SCR 102.

The SCR 102 in FIG. 1 is coupled between the input/output pad I/O and the protected device 101. When an ESD event occurs, the SCR 102 provides a discharge path between the input/output pad I/O to the ground Vss, thereby preventing damage on the protected device 101 by the ESD event.

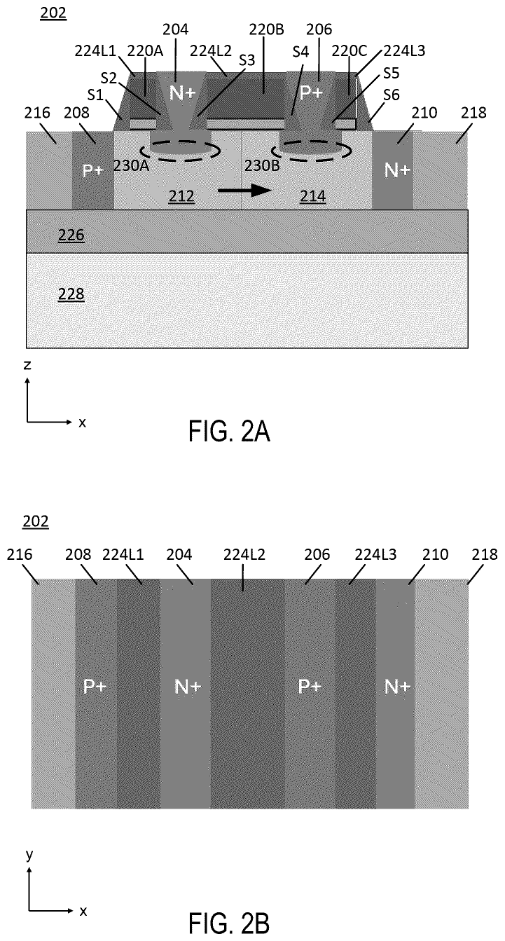

The SCR 102 in FIG. 1 includes junction contacts 104 and well contacts 108. In an embodiment, the junction contacts 104 are raised compared to the well contacts 108, and the well contacts 108 are formed in corresponding wells (e.g., first and second wells 212 and 214 in FIGS. 2A and 2B). As a result, an area of the SCR 102 may be reduced compared to a conventional SCR in which well contacts are formed outside corresponding wells. The raised junction contacts 104 also result in junctions (e.g., first and second junctions 230A and 230B in FIG. 2A) that are substantially parallel to a direction in which a current flows. As a result, junction areas between the junction contacts 104 and the corresponding wells according to an embodiment of the present disclosure are greater than those of the conventional SCR, facilitating control of a relatively large amount of current associated with an ESD event.

In addition, each of the well contacts 108 in FIG. 1 has a relatively large area compared to that of a well contact in a conventional SCR. As a result, a relatively large number of contacts (e.g., metal contacts) can be formed over the well contacts 108, reducing chances of failure in the metal contacts to improve reliability of the SCR.

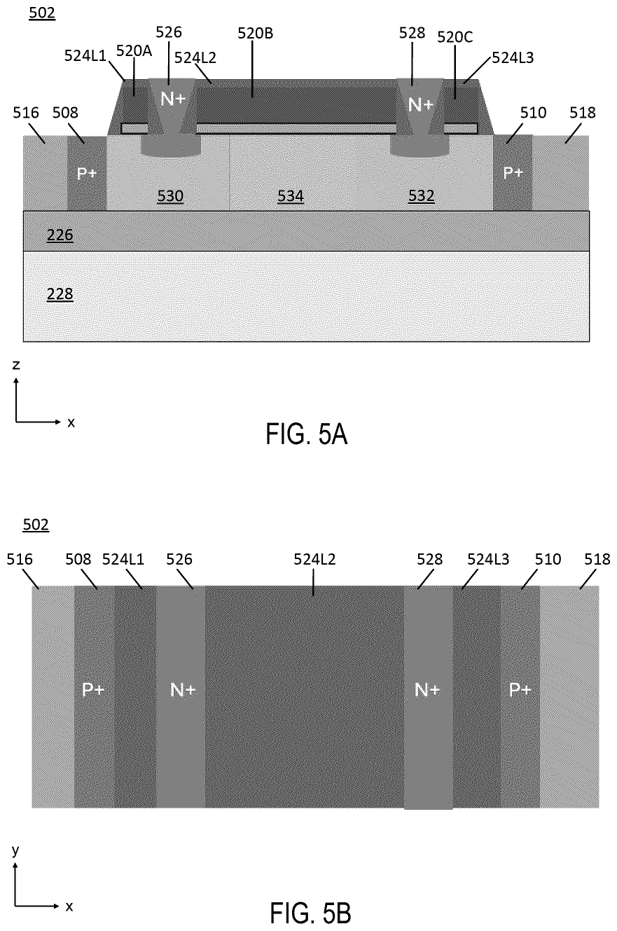

According to an embodiment of the present disclosure, one or more design parameters of the SCR 102 in FIG. 1 may be adjusted to obtain desirable operation characteristics and increase an ESD design window. For example, one or more of a distance between the junction contacts 104, a width of each of the junction contacts 104, and a width of a well (e.g., a third well 534 in FIG. 5A) may be adjusted to obtain desirable I-V characteristics, or leakage current, or both.

FIGS. 2A and 2B illustrate an SCR 202 according to an embodiment. Specifically, FIG. 2A is a simplified cross-sectional view of the SCR 202, FIG. 2B is a simplified top view of the SCR 202. For example, the SCR 202 is a unidirectional SCR.

Referring to FIGS. 2A and 2B, the SCR 202 includes a substrate 228 and an insulation layer 226 over the substrate 228. For example, the insulation layer 226 is a buried oxide (BOX) layer.

The SCR 202 in FIGS. 2A and 2B further includes a first well 212 and a second well 214 over the insulation layer 226. In an embodiment, the first well 212 is a lightly doped P-well and the second well 214 is a lightly doped N-well. For example, a dopant concentration of each of the P-well 212 and the N-well 214 may be in a range from about 10¹⁴ cm⁻³ to about 10¹⁸ cm⁻³. The P-well 212 and the N-well 214 are adjacent to each other, forming a PN junction therebetween.

The SCR 202 in FIGS. 2A and 2B further includes a first well contact 208 in the first well 212 and a second well contact 210 in the second well 214. In an embodiment, the first well contact 208 is heavily doped with P-type dopants, and the second well contact 210 is heavily doped with N-type dopants. For example, a dopant concentration of each of the first well contact 208 and the second contact 210 may be in a range from about 10¹⁸ cm⁻³ to about 10²⁰ cm⁻³. The first well contact 208 may be adjacent to a first shallow trench isolation (STI) 216, and the second well contact 210 may be adjacent to a second STI 218. Since the first and second well contacts 208 and 210 are formed in the first and second wells 212 and 214, respectively, the SCR 202 according to an embodiment of the present disclosure has an area smaller than that of a conventional SCR in which well contacts are formed outside corresponding wells.

Referring to FIG. 2B, when seen in a top view, the first well contact 208 and the second well contact 210 are arranged in a first direction x, and each extend in a second direction y intersecting the first direction x (e.g., orthogonal to the first direction x). As a result, each of the first and second well contacts 208 and 210 has a relatively large area compared to that of a well contact in a conventional SCR. Since a relatively large number of contacts (e.g., metal contacts) can be formed over the first and second well contacts 208 and 210 compared to those in the conventional SCR, chances of failure in the metal contacts may be significantly reduced to improve operation reliability of the SCR 202 according to an embodiment of the present disclosure.

The SCR 202 in FIGS. 2A and 2B further includes a first junction contact 204 and a second junction contact 206. In an embodiment, the first junction contact 204 is heavily doped with N-type dopants and the second junction contact 206 is heavily doped with P-type dopants.

Referring to FIG. 2A, the first junction contact 204 is raised compared to the first well contact 208, and the second junction contact 206 is raised compared to the second well contact 210. In an embodiment, a bottom surface of the first junction contact 204 is raised compared to a bottom surface of the first well contact 208, and a bottom surface of the second junction contact 206 is raised compared to a bottom surface of the second well contact 210. Specifically, the first well contact 208 has a bottom surface that is substantially coplanar with a bottom surface of the first well 212, and the bottom surface of the first junction contact 204 is spaced apart from the bottom surface of the first well 212 by a first height (e.g., a few hundreds of nanometers) in a third direction z. Similarly, the second well contact 210 has a bottom surface that is substantially coplanar with a bottom surface of the second well 214, and the bottom surface of the second junction contact 206 is spaced apart from the bottom surface of the second well 214 by a second height. In an embodiment, the first height may be substantially equal to the second height. For example, a difference between the first height and the second height may be equal to or less than 5%, 3%, or 1% of an average of the first and second heights.

The SCR 202 in FIGS. 2A and 2B further includes first, second, and third polysilicon layers 220A, 220B, and 220C and first, second, and third isolation structures. In an embodiment, the first isolation structure includes a first isolation layer 224L1 and spacers S1 and S2, the second isolation structure includes a second isolation layer 224L2 and spacers S3 and S4, and the third isolation structure includes a third isolation layer 224L3 and spacers S5 and S6. For example, each of the first, second, and third isolation structures includes nitride.

In an embodiment, the first junction contact 204 and the second junction contact 206 are spaced apart in a first direction x to be electrically isolated from each other by the second polysilicon layer 220B and the spacers S3 and S4. In a conventional SCR, a SiN layer is formed over a P-well and a N-well to prevent silicidation, requiring a relatively large lateral dimension of the conventional SCR. Since the second polysilicon layer 220B in the SCR 202 has a lateral dimension (e.g., the horizontal width in the first direction x of FIG. 2A) shorter than that of the SiN layer in the conventional SCR, an area of the SCR 202 according to an embodiment of the present disclosure may be significantly reduced compared to that of the conventional SCR.

Referring to FIGS. 2A and 2B, the first junction contact 204 is adjacent to the spacers S2 and S3, and the second junction contact 206 is adjacent to the spacers S4 and S5. In the embodiment of FIGS. 2A and 2B, each of the first junction contact 204 and the second junction contact 206 is an epitaxial layer that is monocrystalline. However, embodiments of the present disclosure are not limited thereto. In some embodiments, the spacers S2 to S5 may be omitted in the SCR 202 to make the first junction contact 204 adjacent to the first and second polysilicon layers 220A and 220B and the second junction contact 206 adjacent to the second and third polysilicon layers 220B and 220C. In these embodiments, each of the first junction contact 204 and the second junction contact 206 is an epitaxial layer that includes a monocrystalline portion and a polycrystalline portion.

Referring to FIG. 2A, the first junction contact 204 and the first well 212 form a first junction 230A, and the second junction contact 206 and the second well 214 form a second junction 230B. In an embodiment, the first junction contact 204 and the first well contact 208 are coupled to function together as a cathode terminal, and the second well contact 210 and the second junction contact 206 are coupled to function together as an anode terminal. In such an embodiment, when a positive voltage is applied to the cathode terminal and the anode terminal is grounded, a current (indicated by the solid arrow in FIG. 2A) flows in the first direction x substantially parallel to the first and second junctions 230A and 230B. As a result, a junction area of each of the first and second junctions 230A and 230B according to an embodiment of the present disclosure is relatively large, facilitating control of a relatively large amount of current in an ESD event.

In the embodiment of FIG. 2A, each of the bottom surface of the first junction contact 204 and the bottom surface of the second junction contact 206 is a rounded surface to further increase the junction areas of the first and second junctions 230A and 230B. However, embodiments of the present disclosure are not limited thereto. For example, each of the bottom surface of the first junction contact 204 and the bottom surface of the second junction contact 206 may be a substantially planar surface.

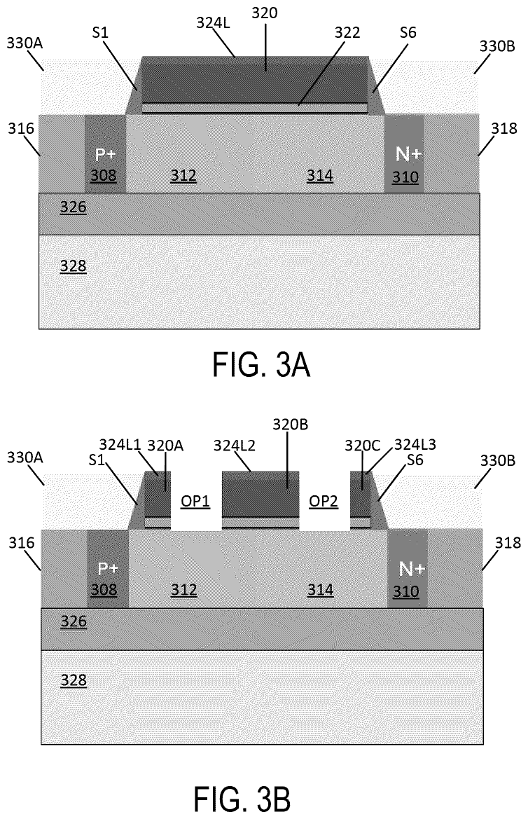

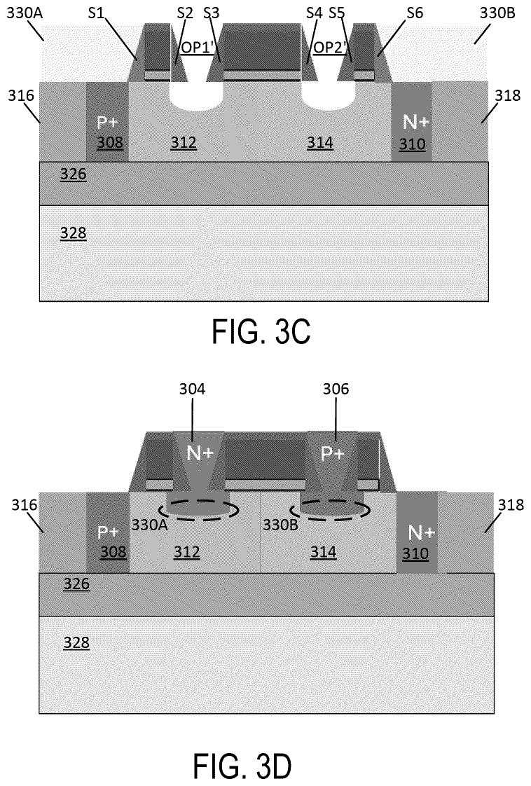

FIGS. 3A, 3B, 3C, and 3D illustrate a method of fabricating an SCR (e.g., the SCR 202 FIGS. 2A and 2B) according to an embodiment.

Referring to FIG. 3A, the method includes providing a structure that includes a substrate 328, an insulation layer (e.g., a BOX layer) 326 over the substrate 328, a first well 312, a second well 314, a first STI 316, and a second STI 318 over the insulator layer 326. The method further includes forming a first well contact 308 in the first well 312 and a second well contact 310 in the second well 314, forming a gate oxide layer 322 and a polysilicon layer 320 over the gate oxide layer 322, and forming an isolation layer 324L, spacers S1 and S6, and first and second oxide layers 330A and 330B. For example, each of the isolation layer 324L and spacers S1 and S6 includes nitride. In some embodiments, after the polysilicon layer 320, the isolation layer 324L, and the spacers S1 and S6 have been formed, the first well contact 308 and the second well contact 310 may be formed to align the first and second well contacts 308 and 310 with the polysilicon layer 320.

Referring to FIG. 3B, the method further includes forming first, second, and third polysilicon layers 320A, 320B, and 320C, and first, second, and third isolation layers 324L1, 324L2, and 324L3. Specifically, the isolation layer 324L, the polysilicon layer 320, and the gate oxide layer 330 in FIG. 3A are etched to form a first opening OP1 and a second opening OP2 that expose the first well 312 and the second well 314, respectively.

Referring to FIG. 3C, the method further includes forming spacers S2, S3, S4, and S5. In an embodiment, an isolation film is deposited over the structure of FIG. 3B, and an anisotropic etch is performed to remove horizontal portions of the deposited film to form the spacers S2, S3, S4, and S5. For example, the isolation film may be deposited using Low Pressure Chemical Vapor Deposition (LPCVD) or Plasma Enhanced Chemical Vapor Deposition (PECVD), and Reactive Ion Etching (RIE) may be performed on the deposited film to form the spacers S2, S3, S4, and S5.

The method in FIG. 3C further includes partially etching the first well 312 and the second well 314 to form a lower portion of a first opening OP1′ and a lower portion of a second opening OP2′, respectively. In the embodiment of FIG. 3C, the first and second openings OP1′ and OP2′ each have a bottom surface that is rounded to increase areas of first and second junction areas 332A and 332B shown in FIG. 3D. For example, the first and second openings OP1′ and OP2′ may be formed using an isotropic etching process. However, embodiments of the present disclosure are not limited thereto. For example, the first and second openings OP1′ and OP2′ each may be formed to have a bottom surface that is substantially planar, using an anisotropic etching process.

Referring to FIG. 3D, the method further includes forming a first junction contact 304 and a second junction contact 306. In an embodiment, first and second epitaxial layers are grown over the first and second wells 312 and 314 to fill the first and second openings OP1′ and OP2′ in FIG. 3C, respectively. Subsequently, the first and second epitaxial layers are doped with N-type and P-type dopants to form the first and second junction contacts 304 and 306, respectively. For example, each of the first and second epitaxial layers is a monocrystalline/or poly crystalline or a mixture of both, and the first and second epitaxial layers are heavily doped with a dopant concentration in a range from about 10¹⁸ cm⁻³ to about 10²⁰ cm⁻³ to form the first and second junction contacts 304 and 306, respectively.

In the embodiments shown in FIGS. 3C and 3D, the first and second openings OP1′ and OP2′ are formed together, and subsequently the first and second junction contacts 304 and 306 are formed together. However, embodiments of the present disclosure are not limited thereto. For example, the first opening OP1′ may be formed, and the first junction contact 304 may be formed in the first opening OP1′. Subsequently, the second opening OP2′ may be formed, and the second junction contact 306 may be formed in the second opening OP2′.

In the embodiments shown in FIGS. 3C and 3D, the method includes forming the spacers S2, S3, S4, and S5. However, embodiments of the present disclosure are not limited thereto. In some embodiments, forming the spacers S2, S3, S4, and S5 shown in FIG. 3C may be omitted, and first and second epitaxial layers may be formed to fill the first and second openings OP1 and OP2 in FIG. 3B. In these embodiments, each of the first and second epitaxial layers includes a monocrystalline portion and a polycrystalline portion, and the first and second epitaxial layers are doped with N-type and P-type dopants to form the first and second junction contacts, respectively.

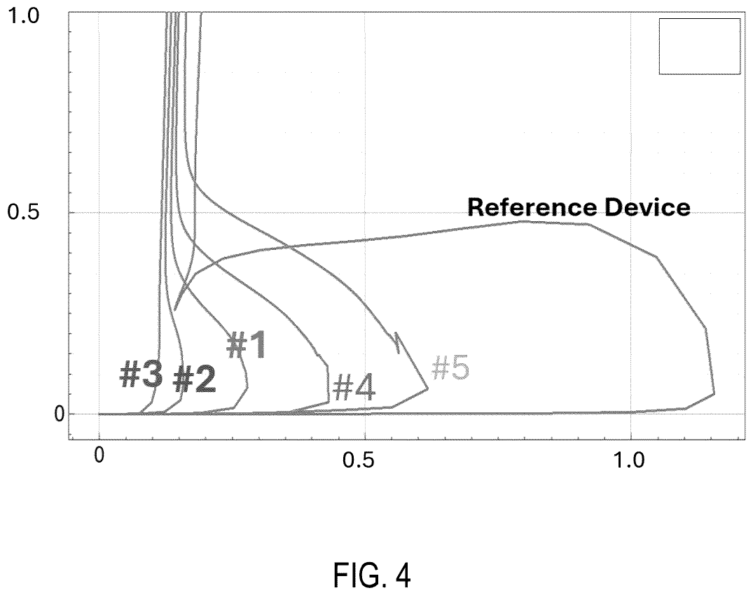

FIG. 4 illustrates normalized I-V characteristics of SCRs according to first, second, third, fourth, and fifth embodiments #1, #2, #3, #4, and #5 of the present disclosure compared to those of a conventional SCR Reference Device. Specifically, Table 1 (below) shows a width of each of first and second junction contacts (e.g., the junction contacts 204 and 206 in FIG. 2A) and a distance between the first and second junction contacts according to first, second, third, fourth, and fifth embodiments #1, #2, #3, #4, and #5.

TABLE 1

| | A width of each junction | | A distance between junction | |
|---|---|---|---|---|
| Embodiment | contact | | contacts | |
| #1 | 0.2 | μm | 0.2 | μm |
| #2 | 0.2 | μm | 0.15 | μm |
| #3 | 0.2 | μm | 0.10 | μm |
| #4 | 0.15 | μm | 0.20 | μm |
| #5 | 0.10 | μm | 0.20 | μm |

Referring to FIG. 4, according to the I-V graphs of the first, second, and third embodiments #1, #2, and #3, when the distance between the junction contacts decreases, trigger voltage and holding current decrease. According to the I-V graphs of the first, fourth, and fifth embodiments #1, #4, and #5, when the width of each junction contact decreases, trigger voltage and holding current increase.

Although not shown, leakage currents may vary according to the first to fifth embodiments #1 to #5. For example, when the width of each junction contact decreases in the fourth and fifth embodiments #4 and #5, leakage current may decrease.

As described above, design parameters (e.g., the distance between the junction contacts and the width of each junction contact) of an SCR may be adjusted to obtain desirable operation characteristics and increase an ESD design window. In an embodiment, one or more of these design parameters may be adjusted to obtain trigger voltage that is sufficiently high to ensure operation reliability of a protected device (e.g., the protected device 101 in FIG. 1) and sufficiently low to prevent significant damage on the protected device.

FIGS. 5A and 5B illustrates illustrate an SCR 502 according to an embodiment. Specifically, FIG. 5A is a simplified cross-sectional view of the SCR 502, and FIG. 5B is a simplified top view of the SCR 502. For example, the SCR 502 is a bidirectional SCR. The SCR in FIGS. 5A and 5B includes similar elements to those of the SCR of FIGS. 2A and 2B, and thus detailed descriptions on these elements may be omitted in the following disclosure for the interest of brevity.

The SCR 502 in FIGS. 5A and 5B includes a first well 530, a second well 532, and a third well 534 between the first well 530 and the second well 532. In an embodiment, the first well 530 is a lightly doped P-well, the second well 532 is a lightly doped P-well, and the third well 534 is a lightly doped N-well.

The SCR 502 in FIGS. 5A and 5B further includes a first well contact 508 in the first well 530 and a second well contact 510 in the second well 532. In an embodiment, each of the first and second well contacts 508 and 510 is heavily doped with P-type dopants. The first well contact 508 may be adjacent to a first shallow trench isolation (STI) 516, and the second well contact 510 may be adjacent to a second STI 518.

The SCR 502 in FIGS. 5A and 5B further includes a first junction contact 526 and a second junction contact 528. In an embodiment, each of the first and second junction contacts 526 and 528 is heavily doped with N-type dopants.

Referring to FIG. 5B, when seen in a top view, the first well contact 508, the first junction contact 526, the second junction contact 528, and the second well contact 510 are arranged in a first direction x, each extending in a second direction y to be parallel to each other. In a conventional bidirectional SCR, a well contact and a junction contact are arranged in the second direction y, each extending in the second direction y. As a result, the bidirectional SCR 502 according to an embodiment of the present disclosure has a length in the second direction y that is significantly shorter than that in the conventional bidirectional SCR, reducing an area of the SCR 502 compared to that of the conventional bidirectional SCR.

An SCR according to an embodiment of the present disclosure includes junction contacts raised compared to well contacts, forming the well contacts in corresponding wells. As a result, an area of the SCR may be reduced compared to a conventional SCR in which well contacts are formed outside the corresponding wells. Such raised junction contacts also result in junctions that are substantially parallel to a direction in which a current flows. As a result, junction areas between the junction contacts and the wells according to an embodiment of the present disclosure are greater than those of the conventional SCR, facilitating control of a relatively large amount of current in an ESD event.

An SCR according to an embodiment of the present disclosure includes well contacts and junction contacts that are arranged in a first direction, each extending in a second direction to be parallel to each other, when seen in a top view. As a result, each of the well contacts has a relatively large area compared to that of a well contact in a conventional SCR. Since a relatively large number of contacts (e.g., metal contacts) can be formed over the well contacts according to such an embodiment of the present disclosure, chances of failure in the metal contacts may be significantly reduced to improve reliability of the SCR. Moreover, a bidirectional SCR according to an embodiment of the present disclosure has a length in the second direction that is significantly shorter than that in a conventional bidirectional SCR having a well contact and a junction contact arranged in the second direction. As a result, an area of the bidirectional SCR according to an embodiment of the present disclosure may be significantly reduced compared to the conventional bidirectional SCR.

An SCR according to an embodiment of the present disclosure includes junction contacts that are spaced apart and electrically isolated from each other by a polysilicon layer. As a result, an area of the SCR according to an embodiment of the present disclosure may be reduced compared to that of a conventional SCR including a SiN layer with a relatively large lateral dimension.

According to an embodiment of the present disclosure, one or more design parameters (e.g., a distance between junction contacts, a width of each junction contact, and a width of a well between junction contacts) of an SCR may be adjusted to obtain desirable operation characteristics and increase an ESD design window.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A silicon controlled rectifier (SCR), comprising:
a first well;
a second well;
a first well contact formed in the first well;
a second well contact formed in the second well;
a first junction contact raised compared to the first well contact; and
a second junction contact raised compared to the second well contact.

2. The SCR of claim 1, wherein the first well is a lightly doped P-well and the second well is a lightly doped N-well, and the P-well and the N-well are adjacent to each other, and
wherein the first well contact and the second junction contact each are heavily doped with P-type dopants, and the second well contact and the first junction contact each are heavily doped with N-type dopants.

3. The SCR of claim 1, further comprising a third well between the first well and the second well,
wherein the first well is a lightly doped P-well, the second well is a lightly doped P-well, and the third well is a lightly doped N-well,
wherein the first well contact and the second well contact each are heavily doped with P-type dopants, and the first junction contact and the second junction contact each are heavily doped with N-type dopants.

4. The SCR of claim 1, wherein the first well contact, the second well contact, the first junction contact, and the second junction contact are arranged in a first direction, and each extend in a second direction intersecting the first direction.

5. The SCR of claim 1, wherein the first junction contact and the second junction contact are spaced apart from each other by a polysilicon layer.

6. The SCR of claim 1, wherein each of the first junction contact and the second junction contact is an epitaxial layer.

7. The SCR of claim 6, wherein the first junction contact is adjacent to a first pair of spacers, the second junction contact is adjacent to a second pair of spacers, and the epitaxial layer is monocrystalline.

8. The SCR of claim 6, wherein the first junction contact is adjacent to a first polysilicon layer and a second polysilicon layer, the second junction contact is adjacent to the second polysilicon layer and a third polysilicon layer, and the epitaxial layer includes a monocrystalline portion and a polycrystalline portion.

9. The SCR of claim 1, wherein the first junction contact and the first well form a first junction, and the second junction contact and the second well form a second junction.

10. The SCR of claim 9, wherein each of a bottom surface of the first junction contact and a bottom surface of the first junction contact is a rounded surface.

11. The SCR of claim 1, wherein a bottom surface of the first well contact is coplanar with a bottom surface of the first well, and a bottom surface of the second well contact is coplanar with a bottom surface of the second well.

12. The SCR of claim 11, wherein a bottom surface of the first junction contact is spaced apart from the bottom surface of the first well by a first height, and a bottom surface of the second junction contact is spaced apart from the bottom surface of the second well by a second height, the second height being substantially equal to the first height.

13. The SCR of claim 1, further comprising:
a substrate; and
an insulation layer over the substrate,
wherein the first well and the second well are formed over the insulation layer.

14. An integrated circuit (IC), comprising:
a protected device; and
a silicon controlled rectifier (SCR) coupled between an I/O pad and the protective device,
wherein the SCR comprises:
a first well;
a second well;
a first well contact formed in the first well;
a second well contact formed in the second well;
a first junction contact raised compared to the first well contact; and
a second junction contact raised compared to the second well contact.

15. The IC of claim 14, wherein the first well is a lightly doped P-well and the second well is a lightly doped N-well, and the P-well and the N-well are adjacent to each other, and
wherein the first well contact and the second junction contact each are heavily doped with P-type dopants, and the second well contact and the first junction contact each are heavily doped with N-type dopants.

16. The IC of claim 14, wherein the SCR further comprises a third well between the first well and the second well,
wherein the first well is a lightly doped P-well, the second well is a lightly doped P-well, and the third well is a lightly doped N-well, and
wherein the first well contact and the second well contact each are heavily doped with P-type dopants, and the first junction contact and the second junction contact each are heavily doped with N-type dopants.

17. The IC of claim 14, wherein the first junction contact and the second junction contact are spaced apart from each other by a polysilicon layer.

18. A method of forming a silicon controlled rectifier (SCR), comprising:
forming a first well contact in a first well;
forming a second well contact in a second well;
forming a first junction contact raised compared to the first well contact; and
forming a second junction contact raised compared to the second well contact.

19. The method of claim 18, further comprising:
forming a polysilicon layer between the first junction contact and the second junction contact.

20. The method of claim 19, wherein forming the first junction contact includes performing epitaxial growth over the first well, and forming the second junction contact includes performing epitaxial growth over the first well.
